(19) United States
(12) Patent Application Publication
(10) Pub. No.: US 2015/0270408 A1
(43) Pub. Date: Sep. 24, 2015

(54) THIN FILM TRANSISTOR ARRAY PANEL AND MANUFACTURING METHOD THEREOF

(71) Applicant: Samsung Display Co., Ltd., Yongin-City (KR)

(72) Inventor: Jun Ho SONG, Seongnam-si (KR)

(21) Appl. No.: 14/480,834

(22) Filed: Sep. 9, 2014

(30) Foreign Application Priority Data
Mar. 18, 2014 (KR) 10-2014-0031848

(51) Int. Cl. H01L 29/786; H01L 29/45; H01L 29/49; H01L 29/66

(52) U.S. Cl. CPC H01L 29/78648; H01L 29/66765; H01L 29/78672; H01L 29/7869; H01L 29/66969; H01L 29/458; H01L 29/45; H01L 29/4908; H01L 29/495

(57) ABSTRACT

A thin film transistor array panel includes: a substrate; a first gate electrode on the substrate; a gate insulating layer on the gate electrode; a semiconductor on the gate insulating layer; an etch stopper on a channel of the semiconductor; a source electrode and a drain electrode on the semiconductor and facing each other with respect to the first gate electrode; and a second gate electrode on the channel of the semiconductor and in a same layer as the source electrode and the drain electrode. The second gate electrode is electrically separated from the source electrode and the drain electrode.

This application claims priority to Korean Patent Application No. 10-2014-0031848 filed on Mar. 18, 2014, and all the benefits accruing therefrom under 35 U.S.C. §119, the entire contents of which are incorporated herein by reference.

### BACKGROUND

(a) Field

The invention relates to a thin film transistor array panel and a manufacturing method thereof, and particularly, the invention relates to a thin film transistor array panel including an etch stopper and a double gate electrode, and a manufacturing method thereof.

(b) Description of the Related Art

A thin film transistor (“TFT”) such as a liquid crystal display element, an organic electroluminescent display element and an inorganic electroluminescent display element, used for a flat panel display, is used as a switching element for controlling respective pixels and a driving element for driving the pixels.

In general, the TFT includes an active layer including source and drain regions doped with a relatively highly concentrated impurity, and a channel region between the source and drain regions. The TFT also includes a gate electrode insulated from the active layer and provided at a region corresponding to the channel region connected to the source and drain regions.

### SUMMARY

An active layer of a thin film transistor includes a semiconductor material such as amorphous silicon and polysilicon. When the active layer includes amorphous silicon, mobility of carriers is reduced and realizing a driving circuit operable at a relatively high rate may be difficult. When the active layer includes polysilicon, the mobility of carriers is increased but a threshold voltage (Vₜₕ) is not uniform and a compensation circuit must be additionally added.

To solve the problem, studies for using an oxide semiconductor for the thin film transistor active layer have been increased. The oxide thin film transistor using the oxide semiconductor for the active layer can be manufactured by a relatively low-temperature process, can be easily manufactured to have a relatively wide area because of an amorphous state thereof, and has excellent electrical characteristics.

One or more exemplary embodiment of the invention provides a thin film transistor array panel providing a uniform threshold voltage (Vₜₕ) and simplifying a manufacturing process thereof through a double gate electrode simultaneously manufactured with a source electrode and a drain electrode, and a manufacturing method thereof.

An exemplary embodiment of the invention provides a thin film transistor array panel including: a substrate; a first gate electrode on the substrate; a gate insulating layer on the gate electrode; a semiconductor on the gate insulating layer; an etch stopper on a channel of the semiconductor; a source electrode and a drain electrode on the semiconductor and facing each other with respect to the first gate electrode; and a second gate electrode on the channel of the semiconductor and in a same layer as the source electrode and the drain electrode. The second gate electrode is electrically separated from the source electrode and the drain electrode.

The thin film transistor array panel may further include an ohmic contact which contacts the semiconductor and is electrically connected to the source electrode or the drain electrode.

The semiconductor may include polysilicon or an oxide semiconductor.

The source electrode, the drain electrode and the second gate electrode may include a same material.

The source electrode, the drain electrode and the second gate electrode may include titanium (Ti).

The etch stopper may include silicon oxide.

The thin film transistor array panel may further include: a passivation layer on the second gate electrode, the source electrode, the drain electrode and the gate insulating layer; a contact hole may be defined in the passivation layer; and a pixel electrode may be on the passivation layer. The pixel electrode may be connected to the drain electrode via the contact hole defined in the passivation layer.

An opening may be defined in the gate insulating layer, and the second gate electrode may be connected to the first gate electrode via the opening defined in the gate insulating layer.

The first gate electrode and the second gate electrode may receive a same voltage.

Another exemplary embodiment of the invention provides a method for manufacturing a thin film transistor array panel, including: forming a first gate electrode on a substrate; forming a gate insulating layer on the first gate electrode; forming a semiconductor on the gate insulating layer; forming a etch stopper on a channel of the semiconductor; and forming a second gate electrode on the channel of the semiconductor, and a source electrode and a drain electrode facing each other with respect to the gate electrode. The second gate electrode is electrically separated from the source electrode and the drain electrode.

According to one or more exemplary embodiment of the thin film transistor and the manufacturing method thereof of the invention, the threshold voltage (Vₜₕ) can be controlled to be uniform by reducing or effectively preventing an inflow of hydrogen (H) into the channel through the double gate configuration, and the thin film transistor can be manufactured through a simple manufacturing process.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 shows a plan view of an exemplary embodiment of a thin film transistor array panel according to the invention.

FIG. 2 shows a top plan view of an exemplary embodiment of a thin film transistor according to the invention.

FIG. 3 shows a cross-sectional view with respect to line III-III of FIG. 1.

FIG. 4 to FIG. 9 show sequential cross-sectional views of an exemplary embodiment of a method for manufacturing a thin film transistor according to the invention.

FIG. 10 shows a plan view of another exemplary embodiment of a thin film transistor array panel according to the invention.

FIG. 11 shows a top plan view of another exemplary embodiment of a thin film transistor according to the invention.

FIG. 12 shows a cross-sectional view with respect to line XII-XII of FIG. 11.

### DETAILED DESCRIPTION OF THE EMBODIMENTS

The invention will be described more fully hereinafter with reference to the accompanying drawings, in which exemplary embodiments of the invention are shown. As those skilled in the art would realize, the described embodiments may be modified in various different ways, all without departing from the spirit or scope of the invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” or “connected to” another element, it can be directly on or connected to the other element or intervening elements may also be present. In contrast, when an element is referred to as being “directly on” or “directly connected to” another element, there are no intervening elements present. As used herein, connected may refer to elements being physically and/electrically connected to each other. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

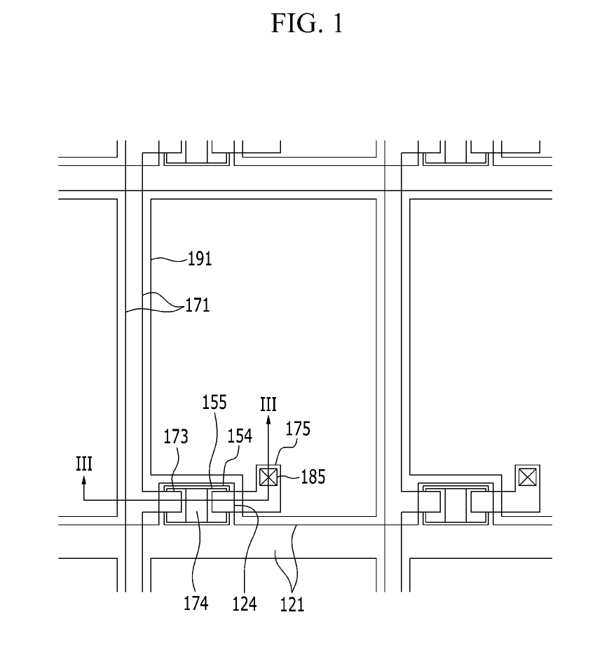

An exemplary embodiment of a thin film transistor and a thin film transistor array panel including the thin film transistor according to the invention will now be described with reference to FIG. 1 to FIG. 3.

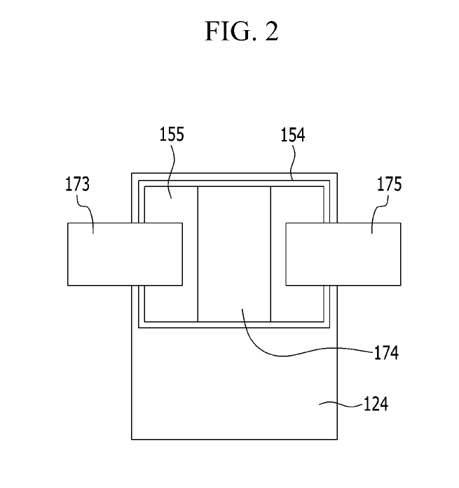

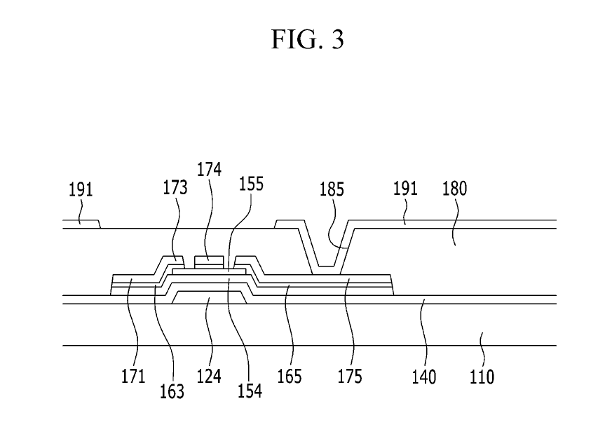

FIG. 1 shows a plan view of an exemplary embodiment of a thin film transistor array panel according to the invention, FIG. 2 shows a top plan view of an exemplary embodiment of a thin film transistor according to the invention, and FIG. 3 shows a cross-sectional view with respect to line III-III of FIG. 1.

Regarding the thin film transistor array panel for a display device according to the invention, a gate line 121 including a first gate electrode 124, a gate insulating layer 140, a semiconductor layer 154, ohmic contacts 163 and 165, an etch stopper 155, a data line 171, a drain electrode 175, and a second gate electrode 174 are sequentially disposed on a substrate 110 which may include an insulating material such as glass and plastic.

The gate line 121 transmits a gate signal and is generally extended in a horizontal direction in the plan view, and the first gate electrode 124 is protruded from a main portion of the gate line 121.

The first gate electrode 124 may include an aluminum-based metal such as aluminum (Al) or an aluminum alloy, a silver-based metal such as silver (Ag) or an silver alloy, a copper-based metal such as copper (Cu) or a copper alloy, a molybdenum-based metal such as molybdenum (Mo) or a molybdenum alloy, chromium (Cr), tantalum (Ta) and titanium (Ti). However, the first gate electrode 124 may have a multilayer configuration including two conductive layers with different physical properties. In an exemplary embodiment, for example, the first gate electrode 124 may have a multilayer configuration of Mo/Al/Mo, Mo/Al, Mo/Cu, CuMn/Cu or Ti/Cu.

The gate insulating layer 140 disposed on the first gate electrode 124 may include an insulating material such as a silicon oxide (SiOx), a silicon nitride (SiNx)and a silicon oxynitride (SiON). In an exemplary embodiment of manufacturing the thin film transistor array panel, the gate insulating layer 140 may be formed by using a sputtering method.

The semiconductor layer 154 provided on the gate insulating layer 140 may include polysilicon or an oxide semiconductor. The oxide semiconductor is a metal oxide semiconductor, and may be a metal oxide such as zinc (Zn), indium (In), gallium (Ga), tin (Sn) and titanium (Ti). A portion of the semiconductor layer 154 is exposed to form a channel of the thin film transistor.

The ohmic contacts 163 and 165 on the semiconductor layer 154 are disposed respectively between the semiconductor layer 154, and the data line 171 and the drain electrode 175, and reduce electrical contact resistance therebetween.

An etch stopper (also called an etching preventing layer) 155 is also provided on the semiconductor layer 154, and covers the channel of the semiconductor layer 154 to reduce or effectively prevent damage or deformation of the channel of the thin film transistor by an etching gas or etchant in a process for etching the source electrode 173 and the drain electrode 175 of manufacturing the thin film transistor array panel. Further, the etch stopper 155 functions to intercept spreading of an impurity, such as hydrogen, to the semiconductor layer 154 from an insulating layer, such as a passivation layer 180, provided on a top portion of the semiconductor layer 154.

The etch stopper 155 may be less than about 3000 angstroms (Å) in cross-sectional thickness, may include an inorganic layer such as a SiOx, a SiNx, a SiOCx, and a SiONx, or may include an organic layer such as an organic material and a polymer organic material. Without being restricted to this, the etch stopper 155 may include a silicon oxide (SiOx) so as to minimize an influence caused by an impurity, such as hydrogen.

The data line 171 transmits a data signal and is extended mainly in a vertical direction in the plan view to cross the gate line 121. The data line 171 includes a source electrode 173 extended from a main portion thereof and toward the first gate electrode 124. The drain electrode 175 is separated from the data line 171 and the source electrode 173, contacts the semiconductor layer 154 and faces the source electrode 173 with respect to the first gate electrode 124.

The semiconductor layer 154 may have an island shape portion, and the semiconductor layer 154 except a separated portion between the source electrode 173 and the drain electrode 175 may have a plane shape that substantially corresponds to the source electrode 173 and the drain electrode 175. Here, the plane shape represents a shape that is seen in a tangential direction of the substrate 110.

FIG. 1 to FIG. 3 show an example in which a portion of the semiconductor layer 154 except the separated portion between the source electrode 173 and the drain electrode 175, has a same plan shape as the source electrode 173 and the drain electrode 175. In an exemplary embodiment of a method manufacturing the thin film transistor array panel, the source electrode 173, the drain electrode 175 and the semiconductor layer 154 may be formed through an exposure process using the same optical mask including a halftone region.

The first gate electrode 124, the source electrode 173 and the drain electrode 175 form a thin film transistor together with the semiconductor layer 154, and the channel of the thin film transistor is formed by a portion of the semiconductor layer 154 exposed between the source electrode 173 and the drain electrode 175.

Further, the second gate electrode 174 is provided on the channel formed by the semiconductor layer 154 exposed between the separated portions of the source electrode 173 and the drain electrode 175 facing each other, and over the etch stopper 155.

The second gate electrode 174 may be electrically separated from the source electrode 173 and the drain electrode 175, and may be disposed to maximally cover the semiconductor layer 154 within a limit of electrical separation from the source electrode 173 and the drain electrode 175.

The particular impurity, such as hydrogen, may be scattered to the semiconductor layer 154 from the insulating layer, such as the passivation layer 180, provided on an upper portion of the semiconductor layer 154 in a subsequent process of the method manufacturing the thin film transistor array panel, and dispersion of the threshold voltage (Vₜₕ) is increased by an inflow of hydrogen so the semiconductor layer 154 may not be formed in a uniform manner.

The etch stopper 155 may intercept spreading of an impurity, such as hydrogen, to the semiconductor layer 154 from the insulating layer, such as the passivation layer 180, provided on the upper portion of the semiconductor layer 154 to a certain degree, but blocking the inflow of hydrogen by more than a predetermined degree by using the etch stopper 155 may be difficult. In the exemplary embodiment, the second gate electrode 174 is provided on the upper portion of the etch stopper 155 to additionally block the inflow of hydrogen to the semiconductor layer 154. The threshold voltage (Vₜₕ) of the thin film transistor may be uniformly formed by effectively twice intercepting the inflow of hydrogen to the semiconductor layer 154 using the second gate electrode 174 and the etch stopper 155.

The second gate electrode 174 may include the same material as the source electrode 173 and the drain electrode 175 and may be in a same layer as the source electrode 173 and the drain electrode 175. The second gate electrode 174 may include an aluminum-based metal such as aluminum (Al) or an aluminum alloy, a silver-based metal such as silver (Ag) or a silver alloy, a copper-based metal such as copper (Cu) or a copper alloy such as copper manganese, a molybdenum-based metal such as molybdenum (Mo) or a molybdenum alloy, chromium (Cr), tantalum (Ta), and titanium (Ti). For example, the molybdenum alloy includes Mo—Nb and Mo—Ti. In addition, the second gate electrode 174, the source electrode 173 and the drain electrode 175 may include a transparent conductive material such as indium tin oxide (“ITO”), indium zinc oxide (“IZO”) and aluminum doped zinc oxide (“AZO”). The second gate electrode 174, the source electrode 173 and the drain electrode 175 may have a multilayer configuration including a plurality of conductive layers (not shown). In one exemplary embodiment, for example, the second gate electrode 174, the source electrode 173 and the drain electrode 175 may have a multilayer configuration such as Mo/Al/Mo, Mo/Al, Mo/Cu, CuMn/Cu and Ti/Cu.

However, in an exemplary embodiment of the invention, the second gate electrode 174 may include a material, such as titanium (Ti), for efficiently absorbing or blocking hydrogen and effectively intercepting the inflow of hydrogen.

The passivation layer 180 including a silicon nitride or a silicon oxide is disposed on the data line 171, the source electrode 173, the second gate electrode 174 and the drain electrode 175.

A contact hole 185 for exposing the drain electrode 175 is defined in the passivation layer 180, and a pixel electrode 191 is disposed on the passivation layer 180 and is connected to the drain electrode 175 via the contact hole 185.

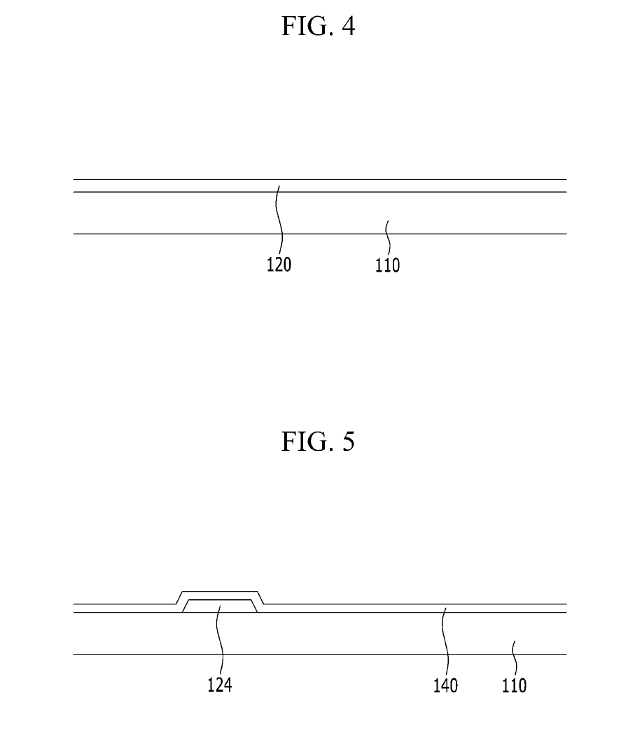

An exemplary embodiment of a method for manufacturing a thin film transistor according to the invention will now be described with reference to FIG. 4 to FIG. 9.

FIG. 4 to FIG. 9 show sequential cross-sectional views of an exemplary embodiment of a method for manufacturing a thin film transistor according to the invention.

Referring to FIG. 4, a gate metal layer 120 is formed on the transparent insulation substrate 110.

The gate metal layer 120 may include an aluminum-based metal such as aluminum (Al) or an aluminum alloy, a silver-based metal such as silver (Ag) or an silver alloy, a copper-based metal such as copper (Cu) or a copper alloy, a molybdenum-based metal such as molybdenum (Mo) or a molybdenum alloy, chromium (Cr), tantalum (Ta) and titanium (Ti). However, the gate metal layer 120 may have a multilayer configuration including two conductive layers with different physical properties. In one exemplary embodiment, for example, the gate metal layer 120 may have a multilayer configuration of Mo/Al/Mo, Mo/Al, Mo/Cu, CuMn/Cu, and Ti/Cu.

As shown in FIG. 5, a first gate electrode 124 is formed from the gate metal layer 120 such as by using an etchant and etching the gate metal layer 120, and the gate insulating layer 140 is formed on the front (e.g., upper surface) of the insulation substrate 110 including the first gate electrode 124.

The gate insulating layer 140 disposed on the first gate electrode 124 may include an insulating material such as a silicon oxide (SiOx), a silicon nitride (SiNx) and a silicon oxynitride (SiON). The gate insulating layer 140 may be formed by using a sputtering method.

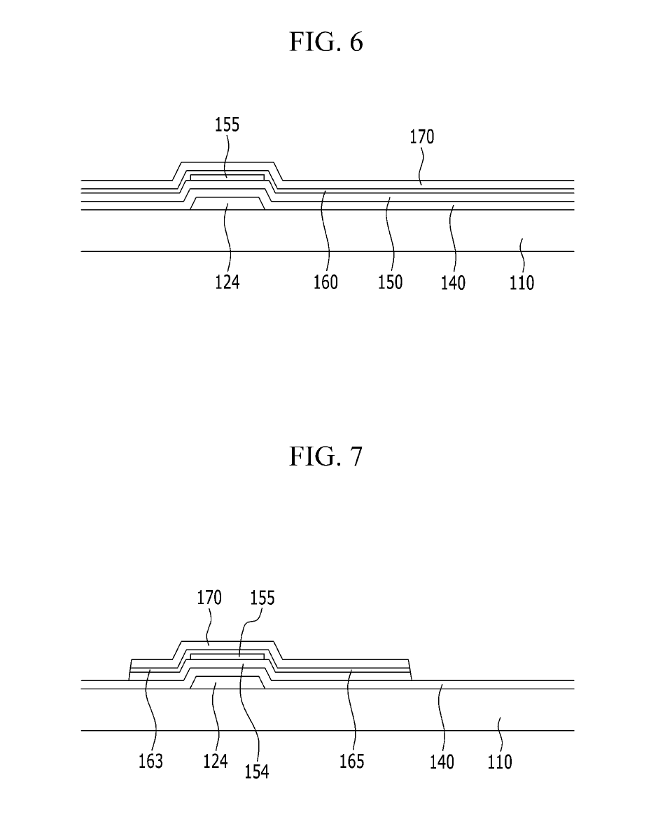

As shown in FIG. 6, an amorphous silicon layer 150 and an impurity-doped amorphous silicon layer 160 are sequentially stacked on the gate insulating layer 140. The etch stopper 155 is stacked on a portion overlapping the first gate electrode 124. A data metal layer 170 is stacked on the impurity-doped amorphous silicon layer 160.

The amorphous silicon layer 150 provided on the gate insulating layer 140 may include polysilicon or an oxide semiconductor. The oxide semiconductor is a metal oxide semiconductor, and may be formed with an oxide of a metal such as zinc (Zn), indium (In), gallium (Ga), tin (Sn), and titanium (Ti), or combinations of the metal and their oxide.

The etch stopper 155 may be less than about 3000 Å in cross-sectional thickness, may be formed with an inorganic layer including SiOx, a SiNx, a SiOCx, a SiONx, or an organic layer including an organic material, or a polymer organic material. Without being restricted to this, the etch stopper 155 may be formed with a silicon oxide (SiOx) so as to minimize an influence caused by an impurity, such as hydrogen.

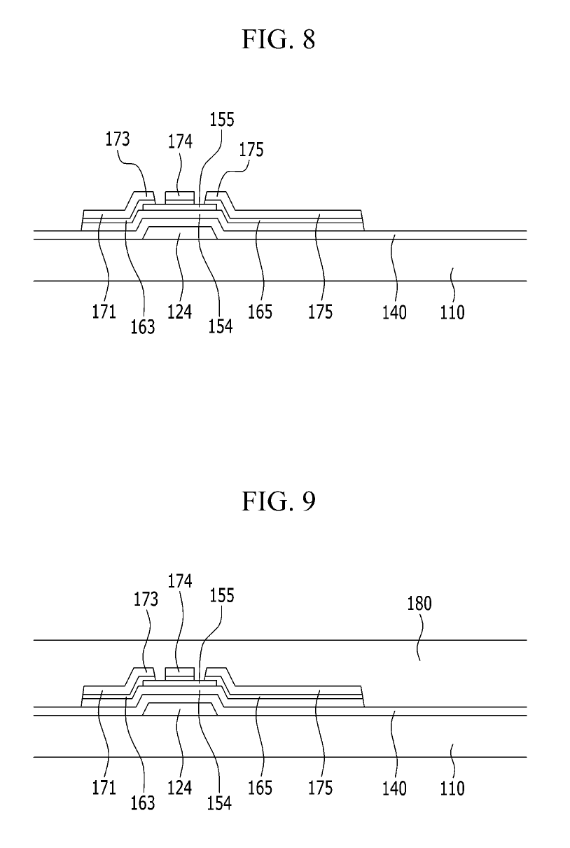

As shown in FIG. 7 and FIG. 8, the data metal layer 170 is etched such as by using an etchant of the data metal layer 170, and a data line 171 including a source electrode 173, a second gate electrode 174 and a drain electrode 175, ohmic contacts 163 and 165, and a semiconductor layer 154, are formed by etching the data metal layer 170, the impurity-doped amorphous silicon layer 160 and the amorphous silicon layer 150, respectively.

In this instance, the second gate electrode 174 is provided on a channel formed by the exposed semiconductor layer 154 between the source electrode 173 and the drain electrode 175 which face each other with respect to the first gate electrode 124, over the etch stopper 155, and formed electrically and/or physically separated from the source electrode 173 and the drain electrode 175. The second gate electrode 174 is in a same layer as the date line 171, source electrode 173 and drain electrode 175, such that the second gate electrode is in a different layer than the first gate electrode 124.

As shown in FIG. 9, a passivation layer 180 is formed on the front of the stacked structure including a second gate electrode 174, the source electrode 173, the data line 171, the drain electrode 175 and the gate insulating layer 140. Referring to FIG. 3, a contact hole 185 for exposing the drain electrode 175 is formed extending through the pass, and a pixel electrode 191 is formed on the passivation layer 180.

The inflow of hydrogen to the semiconductor layer 154, which may occur when the passivation layer 180 is formed, may be efficiently blocked by the etch stopper 155 and the second gate electrode 174.

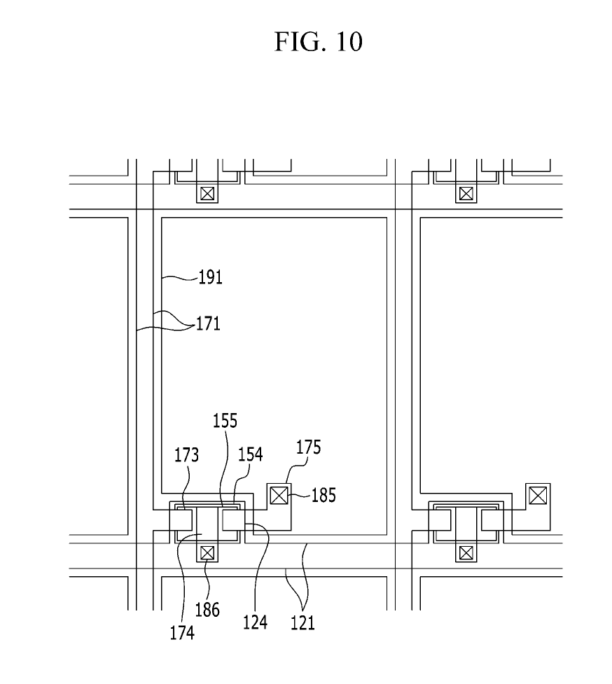

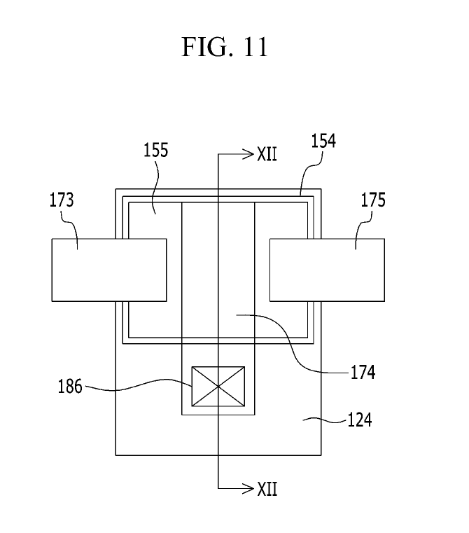

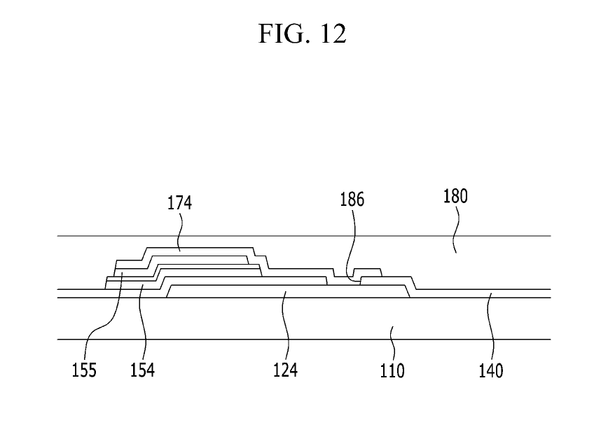

Another exemplary embodiment of a thin film transistor according to the invention will now be described with reference to FIG. 10 to FIG. 12.

The exemplary embodiment of the invention shown in FIG. 10 to FIG. 12 substantially corresponds to the exemplary embodiment shown in FIG. 1 to FIG. 3 except for the configuration of the second gate electrode 174, so repeated descriptions will be omitted.

Referring to FIG. 10 to FIG. 12, an exemplary embodiment of the second gate electrode 174 of the thin film transistor according to the invention may be connected to the first gate electrode 124 through an opening 186 defined in the gate insulating layer 140, and the first gate electrode 124 and the second gate electrode 174 may receive the same voltage. Again, the second gate electrode 174 is in a same layer as the date line 171, source electrode 173 and drain electrode 175, such that the second gate electrode is in a different layer than the first gate electrode 124.

One or more exemplary embodiment of the thin film transistor according to the invention, and the manufacturing method thereof, reduce or effectively prevent the inflow of an impurity, such as hydrogen (H), into the thin film transistor channel, via the double gate configuration to provide a uniform thin film transistor threshold voltage (Vₜₕ) and allow manufacturing of the thin film transistor through a simple manufacturing process.

While this invention has been described in connection with what is presently considered to be practical exemplary embodiments, it is to be understood that the invention is not limited to the disclosed exemplary embodiments, but, on the contrary, is intended to cover various modifications and equivalent arrangements included within the spirit and scope of the appended claims.

What is claimed is:

1. A thin film transistor array panel comprising:
a substrate;
a first gate electrode on the substrate;
a gate insulating layer on the first gate electrode;
a semiconductor on the gate insulating layer;
an etch stopper on a channel of the semiconductor;
a source electrode and a drain electrode on the semiconductor and facing each other with respect to the first gate electrode; and
a second gate electrode on the channel of the semiconductor, and in a same layer as the source electrode and the drain electrode,
wherein
the second gate electrode is electrically separated from the source electrode and the drain electrode.

2. The thin film transistor array panel of claim 1, further comprising:
an ohmic contact which contacts the semiconductor and is connected to the source electrode or the drain electrode.

3. The thin film transistor array panel of claim 2, wherein
the semiconductor comprises polysilicon or an oxide semiconductor.

4. The thin film transistor array panel of claim 3, wherein
the source electrode, the drain electrode and the second gate electrode comprise a same material.

5. The thin film transistor array panel of claim 4, wherein
the source electrode, the drain electrode and the second gate electrode comprise titanium (Ti).

6. The thin film transistor array panel of claim 3, wherein
the etch stopper comprises silicon oxide.

7. The thin film transistor array panel of claim 1, further comprising:
a passivation layer on the second gate electrode, the source electrode, the drain electrode and the gate insulating layer;
a contact hole defined in the passivation layer; and
a pixel electrode on the passivation layer,
wherein
the pixel electrode is connected to the drain electrode via the contact hole defined in the passivation layer.

8. The thin film transistor array panel of claim 7, further comprising:
an opening defined in the gate insulating layer,
wherein
the second gate electrode is connected to the first gate electrode via the opening defined in the gate insulating layer.

9. The thin film transistor array panel of claim 8, wherein
the first gate electrode and the second gate electrode receive a same voltage.

10. A method for manufacturing a thin film transistor array panel, comprising:
forming a first gate electrode on a substrate;
forming a gate insulating layer on the first gate electrode;
forming a semiconductor on the gate insulating layer;
forming a etch stopper on a channel of the semiconductor; and
forming a second gate electrode on the channel of the semiconductor, and a source electrode and a drain electrode facing each other with respect to the gate electrode,
wherein
the second gate electrode is electrically separated from the source electrode and the drain electrode.

11. The method of claim 10, further comprising:
forming a passivation layer on the second gate electrode, the source electrode, the drain electrode and the gate insulating layer, and defining a contact hole in the passivation layer; and
forming a pixel electrode connected to the drain electrode via the contact hole defined in the passivation layer.

12. The method of claim 11, wherein
the semiconductor comprises polysilicon or an oxide semiconductor

13. The method of claim 12, wherein
the source electrode, the drain electrode and the second gate electrode comprise a same material.

14. The method of claim 13, wherein
the source electrode, the drain electrode and the second gate electrode comprise titanium (Ti).

15. The method of claim 12, wherein
the etch stopper comprises silicon oxide.

16. The method of claim 11, further comprising:
forming an ohmic contact which contacts the semiconductor and is connected to the source electrode or the drain electrode.

17. The method of claim 10, further comprising:
forming an opening in the gate insulating layer corresponding to the first gate electrode;
wherein the forming the second gate electrode forms the second gate electrode electrically connected to the first gate electrode via the opening.
